(19) United States
(12) Patent Application Publication
(10) Pub. No.: US 2011/0051388 A1
(43) Pub. Date: Mar. 3, 2011

(54) PRINTED CIRCUIT BOARD WITH A FUSE AND METHOD FOR THE MANUFACTURE OF A FUSE

(76) Inventors: Michael Luppold, Dettenheim (DE); Alexander Dauth, Maulbronn (DE)

(21) Appl. No.: 12/873,616

(22) Filed: Sep. 1, 2010

(30) Foreign Application Priority Data
Sep. 3, 2009 (DE) 10 2009 040 022.2

(51) Int. Cl. H05K 7/00; B23K 31/02; H02B 1/18

(52) U.S. Cl. 361/783; 228/118; 361/834

(57) ABSTRACT

Some invention embodiments relate to a method for forming a fuse which electrically connects two metal surfaces (2) that are arranged on a printed circuit board (5) next to each other and spaced apart from each other. It is provided according to the invention that the two metal surfaces (2) are each partially covered with a protective coating (5), wherein a partial region forming a contact region (2a) remains uncovered, liquid soft solder material (1) which bridges the gap between the two metal surfaces (2) is applied onto the two uncovered partial regions (2a), and the protective coating (5) in a surrounding area of the solder material (1) is removed after the soft solder material (1) has solidified, in order to form receiving regions (2b) which are wetted by the solder material (1) when the latter fuses, with the result that the solder material (1) flows off from a printed circuit board region (3) between the two metal surfaces (2) and the electrical contact formed by the solder material (1) is interrupted. Furthermore, other invention embodiments relate to a printed circuit board with such a fuse.

### FIELD

One aspect of the invention relates to a method for forming a fuse which electrically connects two metal surfaces that are arranged on a printed circuit board next to each other and spaced apart from each other. Furthermore, another aspect of the invention relates to a printed circuit board with such a fuse.

### BACKGROUND

In the event of a fault, circuits arranged on printed circuit boards can result in extreme overtemperatures. To be protected, circuits are, therefore, usually equipped with fuses, temperature switches, current-limiting PTC elements, or similar components.

### SUMMARY

The present invention aims at presenting a way of reliably achieving as cost-effectively as possible and with as low space requirements as possible that, in the event of a fault, a load current can be interrupted or, at least, be reduced as far as necessary to prevent secondary damage.

This problem is solved by a method according to the invention comprising the feature presented in Claim 1 as well as by a printed circuit board with a fuse according to Claim 8. Advantageous further developments of the invention are the subject matter of subordinate claims.

A fuse according to the invention bridges a gap between two metal surfaces with soft solder material such that an electrical contact can be established between the two metal surfaces, said metal surfaces being arranged on the printed circuit board next to each other. Therein, the soft solder material covers only a part of each of the metal surfaces. A further part of the metal surfaces in the environment of the soft solder material forms receiving regions which receive molten solder material when the fuse responds. The interfacial energy between the solder material and the receiving regions is lower than the interfacial energy between the solder material and the printed circuit board surface between the two bridged metal surfaces. When the solder material fuses, the receiving regions are, therefore, wetted with liquid solder material, with the result that solder material flows off from the printed circuit board region between the two metal surfaces and the electrical contact formed by the solder material is interrupted.

In the method according to the invention, the receiving regions are formed by covering the corresponding regions of the two metal surfaces with a solder-resistant protective coating prior to applying the solder material. Subsequently, liquid solder material which bridges the gap between the two metal surfaces is applied onto the partial surfaces that are not covered by the protective coating. After the solder material has solidified, the protective coating in the environment of the solder material is removed, with the result that receiving regions are produced that can be wetted with molten solder material.

Metallized surfaces of a printed circuit board, for example, metal surfaces that are made of copper, can be wetted with solder material much more easily than customary synthetic resin surfaces of printed circuit boards. The interfacial energy between the solder material and the synthetic resin, in particular epoxy resin, is therefore higher than the interfacial energy between the solder material and a metal surface, in particular copper. When it fuses, the solder material, therefore, flows off from the printed circuit board region between the two metal surfaces and wets the receiving regions.

In order to improve the wettability of the receiving regions, these regions are covered with flux, preferably at least in part. Suitable fluxing agents are, in particular, fluxing agents that are based on natural or modified resins, for example, rosin, to which activation additives, such as acids, more particularly stearic acid, salicylic acid and/or adipic acid, may be added. Such fluxing agents are, for example, called F-SW 31, F-SW 32, F-SW 33, or F-SW 34. It is also possible to use fluxing agents which contain zinc chloride and/or ammonium chloride if they are provided in an organic preparation, for example, higher alcohols or fats.

In order to cause the contact between the two metal surfaces to be interrupted when the solder fuses, it is actually sufficient to provide a receiving region or reservoir on one side of the bridged gap. Preferably, however, receiving regions are provided on either side of the gap that is bridged by the solder material. That means that the two metal surfaces each form a contact region that is covered with solder material as well as a receiving region.

Preferably, the at least one receiving region surrounds the solder material, for example, in the form of a U or a C. This allows achieving that liquid solder material can wet the receiving regions particularly rapidly. This is to advantage in that the fuse can respond with corresponding rapidness.

Together, the receiving regions are, preferably, at least as large as the printed circuit board region between the two metal surfaces that is covered with solder material. This measure is to advantage in that solder material covering the printed circuit board between the two metal surfaces can migrate into the receiving regions almost completely when the cut-out responds.

According to common linguistic usage, a soft solder material is to be interpreted as a solder material the melting point of which is less than 450° C. Preferred use is made of solder material with a considerably lower melting point, for example, less than 250° C., more particularly less than 200° C. Suitable are, for example, tin alloys, in particular tin-lead alloys and/or indium alloys.

### BRIEF DESCRIPTION OF THE DRAWINGS

Further details and advantages of the invention will be illustrated by means of exemplary embodiments of the invention with reference being made to the accompanying drawings. Therein, equal parts that are corresponding to each other are designated with corresponding reference symbols. In the Figures,

FIG. 1 shows a schematic diagram of a fuse;

FIG. 2 shows the metal surfaces of FIG. 1, said surfaces being bridged by solder material;

FIG. 3 shows a lateral view of FIG. 1;

FIG. 4 shows the fuse shown in FIG. 1 in the tripped state;

FIG. 5 shows a further exemplary embodiment of a fuse in the tripped state; and

FIG. 6 shows a sectional view of FIG. 5.

### DETAILED DESCRIPTION

Before discussing example embodiments of the invention, it will be appreciated that the present invention includes methods as well as apparatuses. Methods of the invention may be useful to make apparatuses of the invention. It will therefore be appreciated that in describing a method of the invention description of an apparatus may be had, and vice versa.

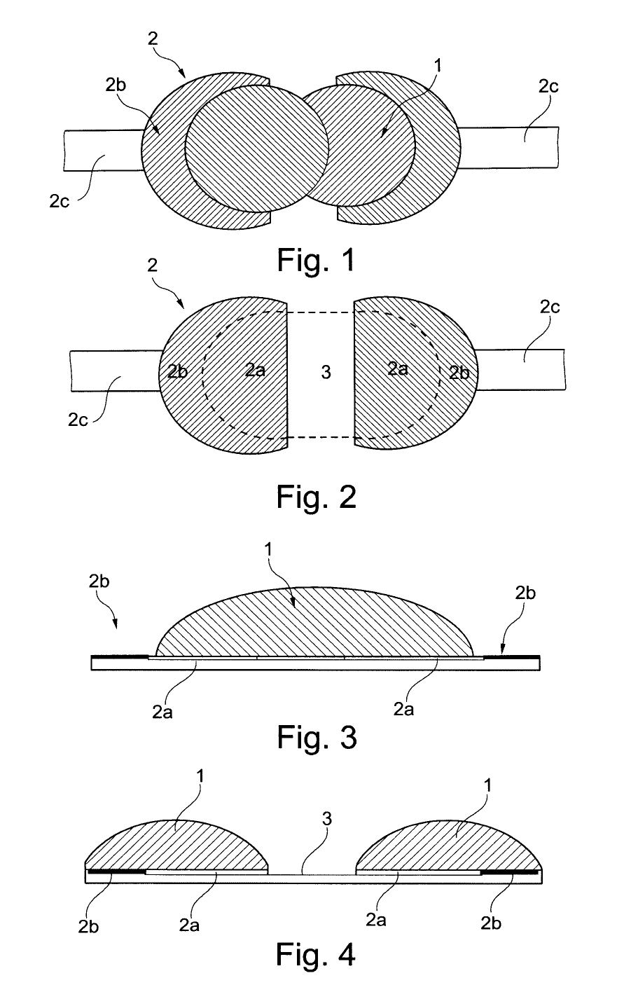

FIG. 1 shows a schematic diagram of the structure of an exemplary embodiment of a fuse according to the invention. The fuse is formed by soft solder material 1, for example, L-Sn60PbAg or an indium alloy, which covers a contact region 2a of each of two metal surfaces 2 and bridges a gap therebetween. As shown in FIG. 1, the soft solder material 1 covers only a part of each of the two metal surfaces 2. A partial region 2b that is arranged adjacent to the contact region 2a and is covered by the soft solder material 1 is free from the solder material 1 and forms a receiving region which is wetted with molten solder material 1 if the cut-out responds.

FIG. 2 shows the metal surfaces 2 of the exemplary embodiment shown in FIG. 1 without any solder material 1. Therein, the contact regions 2a that are covered with soft solder material 1 and the receiving regions 2b that are not covered with soft solder material are plotted in the metal surfaces 2.

When the solder material 1 fuses, the receiving regions 2b are wetted by the solder material 1. As a result, the solder material 1 is drawn off from the printed circuit board region 3 between the two metal surfaces 2 and the electrical contact formed by the solder material 1 is interrupted.

FIG. 3 shows a lateral view of FIG. 1 in a schematic diagram. FIG. 4 shows a corresponding lateral view after the fuse has tripped. In the tripped state, the solder material 1 wets the receiving regions 2b which surround the contact regions 2a. The section 3 of the printed circuit board surface that is disposed between the two metal surfaces 2 is largely free from solder material 1 when the fuse is in the tripped state.

To manufacture the fuse shown in FIG. 1, the partial surfaces of the metal surfaces 2 that are provided for the receiving regions 2b are, in a first step, covered with a solder-resistant protective coating, for example, masking lacquer. Subsequently, the parts of the metal surfaces 2 that are provided as contact regions 2a and are not covered with the solder-resistant protective coating are covered with liquid solder material 1. The solder material 1 applied therein is also used to bridge the gap 3 on the printed circuit board surface that is existing between the contact regions 2a, with the result that the two metal surfaces 2 are connected by the solder material 1 in an electrically conducting manner. After the solder material 1 has solidified, the protective coating is removed from the receiving regions 2b.

In order to improve the wettability of the receiving regions 2b, these regions can be covered with flux either partially or completely. The metal surfaces 2 are made of a material that is customary for solder tracks, for example, copper with potential coatings. In the exemplary embodiment shown, the receiving regions 2b and the contact regions 2a are, together, designed as extended end sections of the pcb-tracks 2c. The printed circuit board region 3 that is disposed between the two metal surfaces 2 and is covered with the solder material 1 can, for example, consist of an epoxy resin that is customary for printed circuit boards.

The receiving regions 2b surround the contact regions 2a in the form of a U or a C. When the cut-out trips, molten solder material 1 can, therefore, flow across an advantageously large circumferential surface and into the receiving regions 2b. Together, the receiving regions 2b are, preferably, larger than the surface 3 that is disposed between the two metal surfaces 2 and is covered with solder material 1. In this manner, there is sufficient space to receive the solder material 1 bridging the gap 3 between the two metal surfaces 2 when the cut-out trips. In the schematic diagram of FIG. 1, the receiving regions 2b appear to be somewhat smaller than the contact regions 2a surrounded by said receiving regions 2b. Preferably, however, the receiving regions 2b are at least as large as the contact regions 2a surrounded by said receiving regions 2b.

The fuse described above can, for example, be used in the event of a fault to interrupt a load current of a field-effect transistor, more particularly of a MOSFET, arranged on the printed circuit board. To achieve this, the fuse is thermally coupled to the field-effect transistor, for example, by being arranged in the immediate vicinity of the transistor. During operation, a load current to be switched by the field-effect transistor flows through the fuse. In the event of a fault, a heating of the field-effect transistor causes the solder material 1 to fuse, which will then wet the receiving regions 2b and, therein, flow off from the space between the two contact regions 2a, with the result that the cut-out responds and an electrical contact between the two metal surfaces 2 is interrupted.

In the exemplary embodiment shown in FIGS. 1 to 4, the two metal surfaces 2 each have a straight edge on their sides that are facing each other. However, other shapes are also possible in addition thereto. For example, one of the two contact regions 2a can have an indentation on its edge, with the other contact region 2a projecting into said indentation with a projection formed on its edge. In particular, the contact regions 2a can engage each other in a toothed manner.

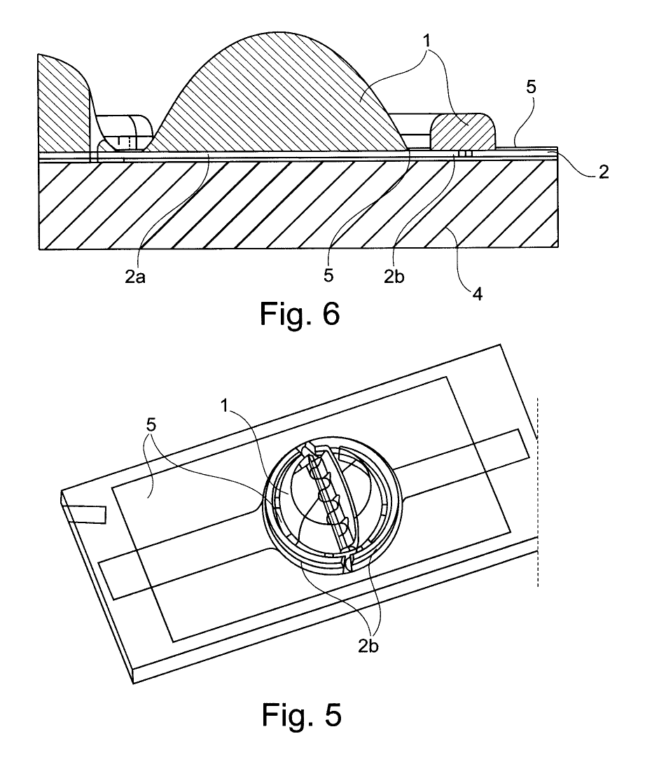

FIG. 5 show a schematic diagram of a corresponding exemplary embodiment of a fuse in the tripped state. In this context, FIG. 6 shows a sectional view of a detail of FIG. 5. In the exemplary embodiment shown in FIG. 5, the two contact regions 2a that are covered with solder material 1 engage each other in the manner of a meander. The contact regions 2a are surrounded by C-shaped receiving regions 2b which are also covered with solder material 1 because the cut-out is shown in the tripped state.

A special feature of the exemplary embodiment shown in FIGS. 5 and 6 is that the solder-resistant protective coating 5 has not been completely removed from the metal surfaces 2 but continues to cover partial surfaces between the contact region 2a and the receiving region 2b. In this exemplary embodiment, the protective coating 5 was only removed in a few transition regions which connect the receiving regions 2b with the contact regions 2a.

FIG. 6 shows the printed circuit board 4, the metal surfaces 2 arranged thereon, the solder material 1, and the protective coating 5 which, in the exemplary embodiment shown in FIG. 5, has not been completely removed from the metal surfaces 2.

FIG. 6 shows the solder material 1 schematically. In fact, the shape of a solder drop that results when solder material fuses and subsequently solidifies is an approximately symmetrical dome. Some of the edges of the solder material 1 are shown excessively steep in FIG. 6.

### REFERENCE SYMBOLS

1 Solder material
2 Metal surfaces
2a Contact region
2b Receiving region
2c Track
3 Printed circuit board surface between the metal surfaces
4 Printed circuit board
5 Protective coating

In considering the above description and attached Figures, it will be appreciated that some example embodiments of the invention have been shown and described. Many other embodiments are possible and within the scope of the invention as claimed. Also, substitutes and equivalents to various elements of invention embodiments will be apparent to those knowledgeable in the art involved. Various steps of example methods could be changed in order, different elements from different embodiments interchanged with one another, and the like.

1. A method for forming a fuse which electrically connects two metal surfaces that are arranged on a printed circuit board next to each other and spaced apart from each other, comprising the steps of:
partially covering the two metal surfaces with a protective coating, while a partial region forming a contact region remains uncovered,
applying liquid soft solder material onto the two uncovered partial regions to bridges the gap between the two metal surfaces and
after the soft solder material has solidified, removing the protective coating in a surrounding area of the solder material to form receiving regions which are wetted by the solder material when the latter fuses, with the result that solder material flows off from a printed circuit board region between the two metal surfaces and the electrical contact formed by the solder material is interrupted.

2. The method according to claim 1, wherein the protective coating is formed by solder mask.

3. The method according to claim 1, wherein the protective coating is removed through the influence of radiation.

4. The method according to claim 1, wherein the protective coating is designed as a film and is removed by being pulled off.

5. The method according to claim 1, wherein flux is applied onto the two metal surfaces.

6. The method according to claim 1, wherein the protective coating is applied such that it surrounds the contact region.

7. The method according to claim 1, wherein the protective coating is applied such that it surrounds the contact region in the form of a bend.

8. A printed circuit board with a fuse which connects two metal surfaces in an electrically conducting manner, said metal surfaces being arranged next to each other and spaced apart from each other, wherein
the fuse is formed by a soft solder material which covers a contact region of each of the two metal surfaces and bridges the gap therebetween,
a partial region of at least one of the metal surfaces that is arranged adjacent to the contact region is free from solder material and forms a receiving region that can be wetted by molten solder material, said receiving region being wetted by the solder material when the latter fuses, with the result that solder material is drawn off from a printed circuit board region between the two metal surfaces and the electrical contact formed by the solder material is interrupted.

9. The printed circuit board according to claim 8, wherein on both metal surfaces, a partial region adjacent to the contact region is free from solder material and forms a receiving region for molten solder material.

10. The printed circuit board according to claim 8, wherein the receiving regions enclose the contact regions.

11. The printed circuit board according to claim 8, wherein the receiving regions enclose the contact regions in the shape of a U or a C.

12. The printed circuit board according to claim 8, wherein the receiving region is covered with flux at least in part.

13. The printed circuit board according to claim 8, wherein together, the receiving regions are at least as large as the printed circuit board region between the two contact regions that is covered with solder material.

14. The printed circuit board according to claim 8, wherein together, the receiving regions are at least as large as the area of the two contact regions taken together.

15. The printed circuit board according to claim 8, wherein at least one of the contact regions has an indentation on its edge, with the other contact region projecting into said indentation with a bulge formed on its edge.

16. The printed circuit board according to claim 8, wherein each of the two receiving regions is larger than the area of the contact region surrounded thereby.

17. The printed circuit board according to claim 8, wherein between the two contact regions, the printed circuit board comprises a surface of synthetic resin that is covered with the soft solder material.

18. The printed circuit board according to claim 8, wherein the printed circuit carries a field-effect transistor that is thermally coupled to the fuse and is intended to switch a current flowing through the fuse.

19. The printed circuit board according to claim 8, wherein the receiving region is formed at a broadened end of a track.

20. A printed circuit board comprising:
two metal surfaces arranged next to each other and spaced apart from each other, each metal surface having a contact region, at least one of the contact regions having an indentation and the other contact region having a bulge that projects into the indentation,
a gap defined between the two metal surfaces;
a fuse electrically connecting the two metal surfaces, the fuse formed by a soft solder material which at least partially covers the contact region of each of the two metal surfaces and bridges the gap therebetween,
a receiving region of at least one of the metal surfaces formed at the broad end of a track and arranged about the contact region in the general shape of a C and free from solder material, each receiving region having an area that is larger than the area of the contact region it is adjacent to, the receiving region configured to be wetted by molten solder material when the solder material fuses, with the result that solder material is drawn off from a printed circuit board region between the two metal surfaces and the electrical contact formed by the solder material is interrupted; and,
a field-effect transistor thermally coupled to the fuse and configured to switch a current flowing through the fuse.
